(19) United States
(12) Patent Application Publication
(10) Pub. No.: US 2016/0313404 A1
(43) Pub. Date: Oct. 27, 2016

(54) Methods and Systems for Determining the Initial State of Charge (iSoC), and Optimum Charge Cycle(s) and Parameters for a Cell

(71) Applicant: Eargo, Inc., Mountain View, CA (US)

(72) Inventor: Bret Herscher, Cupertino, CA (US)

(21) Appl. No.: 15/098,940

(22) Filed: Apr. 14, 2016

Related U.S. Application Data
(60) Provisional application No. 62/151,067, filed on Apr. 22, 2015.

(51) Int. Cl. G01R 31/36

(52) U.S. Cl. CPC G01R 31/3648; G01R 31/3658; G01R 31/3675

(57) ABSTRACT

Disclosed are method and systems for determining the initial state of charge (iSoC) and current state of charge (SoC) for a cell comprising determining a plurality of cell parameters, including current (i), open circuit voltage (OCV), temperature (T) and time to maximum voltage threshold (t,) of the cell, determining a plurality of cell iSoC parameters as a function of the plurality of cell parameters; determining an adjusted time to maximum voltage threshold (t′_{cv}) of the cell; and determining a corrected iSoC parameter as a function of a predictor-corrector algorithm, the corrected iSoC parameter representing an estimated iSoC of said cell. Also disclosed are methods for determining optimum charge cycle(s) and parameters for the cell based on the corrected iSoC parameter.

### CROSS-REFERENCE TO RELATED APPLICATIONS

This application claims the priority of U.S. Provisional Application No. 62/151,067, filed on Apr. 22, 2015.

### FIELD OF THE INVENTION

The present invention is directed to methods and systems for determining the initial state of charge (iSoC) and current state of charge (SOC) of a cell and, based thereon, the optimum charge cycle(s) and parameters for the cell.

### BACKGROUND OF THE INVENTION

Many power applications require a well-designed cell management system for operational safety and performance. Cell management systems are configured to monitor a current status of a cell, and regulate charging and discharging processes.

One fundamental function of cell management systems is to estimate the initial state of charge (iSoC) and current state of charge (SOC) of a cell. At present, there is an increasing emphasis on model-based methods to estimate iSoC of a cell.

Since a good model is a prerequisite, model-based iSoC estimation typically uses dynamic modeling and parameter identification. However, accurate parameter identification is difficult for the following reasons. First, the parameters for a cell model change over time and with varying operational conditions. Second, the internal resistance increases and the capacity decreases as a result of cell aging. Third, the charging and discharging efficiencies are dependent on the iSoC and the cell current and temperature. Finally, the cell parameters can differ from one cell to another, making cell parameter identification for each cell difficult. Therefore, adaptive methods are preferred, which perform cell parameter identification and iSoC estimation jointly.

Various adaptive models have thus been employed to estimate iSoC of a cell. Illustrative are the models disclosed in U.S. Pat. No. 8,626,679 and U.S. Pat. Pub. Nos. 2014/0172333 and 2014/0214348.

U.S. Pat. No. 8,626,679 discloses a model that is configured to estimate the state of charge (SoC) of a cell using a fusion type soft computing algorithm that is continuously updated by a back-propagating learning algorithm. The disclosed model requires comparator hardware configured to compare the cell SOC estimation value with a predetermined target value that varies with the charging or discharging of the cell. The comparator hardware further provides an algorithm update signal to the processor to update the back-propagating learning algorithm.

U.S. Pat. Pub. No. 2014/0172333 discloses a model that is configured to estimate the SoC of a cell by receiving a voltage corresponding to a SoC of a cell, converting the voltage to an estimated state of charge using different algorithms across different ranges.

U.S. Pat. Pub. No. 2014/0214348 discloses a model that is configured to estimate the SoC of a cell by constructing a set of two or more cell models, where each constructed cell model is associated with an adaptive SOC estimator. The cell models are constructed by measuring the conditions of the cell, determining the weights for the conditions to form SoC estimates and fusing the SoC estimates.

There are several major drawbacks and disadvantages associated with disclosed adaptive models. A major drawback is that the models are limited to the estimation of the SoC of a cell only. The disclosed models require that the charging hardware always remain in direct contact with the cell to accurately estimate the SoC. It is the essence of the present invention to provide a model of determining the initial state of charge (iSoC) for a cell that is frequently separated from the charging hardware.

Another conventional means of estimating the SoC of a cell is commonly referred to as “Coulomb counting.” Coulomb counting consists of monitoring the current output of a cell over time and comparing the current output against a set cumulative current output value that is known to drain a cell. The set cumulative current output value that is known to drain a cell is, however, based on the assumption that the cell has a static total charge capacity.

Coulomb counting is thus analogous to monitoring the fuel level in an automobile by monitoring the fuel flow from a fuel tank having a static volume.

There are also several drawbacks and disadvantages associated with Coulomb counting. A major disadvantage of Coulomb counting is that the method is dependent on the cell having a static total charge capacity. As is well established in the art, a cell has a highly dynamic total charge capacity that is dependent on the number of factors, such as charge cycles, temperature, age of the cell. etc.

By virtue of a cell's dynamic total charge capacity, Coulomb counting will inherently determine inaccurate SoC values. e.g. Coulomb counting could reflect that a cell is fully charged, i.e. a SoC of 100%, when the true SoC of the cell is 86%.

Another disadvantage of Coulomb counting is that method is dependent on “uninterrupted” monitoring of the current output of a cell. If monitoring of current output of a cell is interrupted, e.g. power to a hearing device is turned off, the Coulomb counting reference point reflecting the cumulative current output of the cell is erased, which requires the use of a zero (0) cumulative current output reference point for successive Coulomb counting. Frequent interruptions of Coulomb counting will thus result in substantially inaccurate SoC values.

A further disadvantage of Coulomb counting is that a device that houses a cell, such as a hearing device, will require additional hardware, such as an ammeter configured to monitor the current output of the cell and memory means configured to retain data reflecting the current output data of the cell. The additional hardware will also increase the size of the device, which poses a significant problem for in-ear hearing devices.

It would thus be desirable to provide methods and systems for accurately determining the initial state of charge (iSoC) and current state of charge (SOC) of a cell and, based thereon, the optimum charge cycle(s) and parameters for the cell.

It is therefore an object of the invention to provide methods and systems for accurately determining the initial state of charge (iSoC) and current state of charge (SOC) of a cell and, based thereon, the optimum charge cycle(s) and parameters for the cell.

It is another object of the invention to provide methods and systems for modulating cell charge cycles and parameters that are configured to provide a cell iSoC voltage threshold to limit additional charge cycles, whereby the operational life of the cell is extended.

It is another object of the invention to provide methods and systems for determining cell parameters that are configured to prevent the transmission of current to a cell exhibiting maximum cell voltage, which prevents aberrant and often irreversible changes in the cell's chemistry.

It is another object of the invention to provide methods and systems that provide useful feedback to the user, such as accurately determined current SoC and remaining charge time communicated through an interface device.

### SUMMARY OF THE INVENTION

As indicated above, the present invention is directed to methods and systems for determining. the initial state of charge (iSoC) and current state of charge (SOC) of a cell and, based thereon, the optimum charge cycle(s) and parameters for the cell. As discussed in detail below, the methods of the invention are based in significant part on the finding that, with many cell chemistries, the amount of time required for a cell to attain a constant voltage threshold (CVT) at a constant charge current (t) is strongly related to the iSoC of the cell when the charge cycle is commenced (see FIG. 5).

It has also been found that, with most cell chemistries, the amount of time in the constant current phase to reach CVT (“t_{cv}”) and the iSoC of a cell is a substantially linear relationship, which varies as a function of temperature, as shown in FIG. 7.

As discussed in detail below, the noted relationship between t_{cv} and iSoC of a cell is also employed in the methods of the invention to accurately predict the iSoC at any given point in a charge cycle.

In one embodiment of the invention, there is thus provided a method for determining an estimated initial state of charge (iSoC) of a cell, comprising the steps of:

(i) determining current (i), open circuit voltage (OCV), temperature (T) and base line time to maximum voltage threshold (t_{cv}) of a cell;

(ii) determining a first iSoC parameter as a function of the cell OCV and temperature (T), the first iSoC parameter representing a first estimate of iSoC of the cell;

(iii) determining a second iSoC parameter by discharging voltage (V) from the cell at a constant current (Iₜᵣᵢₐₗ), the second iSoC parameter representing a second estimate of iSoC of the cell;

(iv) determining a third iSoC parameter as a function of the time to maximum voltage threshold (t_{cv}) of the cell and the cell's voltage threshold, the third iSoC parameter representing a third estimate of iSoC of the cell;

(v) determining the lowest iSoC parameter from the first, second and third iSoC parameters;

(vi) determining an adjusted time to maximum voltage threshold (t′_{CV}) of the cell; and

(vii) determining a corrected iSoC parameter as a function of a predictor-corrector algorithm, the corrected iSoC parameter representing an estimated iSoC of the cell.

In some embodiments of the invention, the cell constant current (Iₜᵣᵢₐₗ) is in the range of C/20 to C/5 mA, where C comprises a milliamp per hour (mAh) rating of the cell.

In a preferred embodiment of the invention, the adjusted time to maximum voltage (t′_{CV}) is determined by linearly extrapolating a curve representing time to maximum voltage (t_{CV}) of the cell.

In a preferred embodiment of the invention, the predictor-corrector algorithm determines a further adjusted time to maximum voltage threshold (t″_{cv}) of the cell and compares the further adjusted time to maximum voltage threshold (t″_{cv}) to a plurality of base line time to maximum voltage threshold (t_{BLCV}) values derived from a plurality of base line iSoC curves for a similar cell to determine the estimated iSoC of the cell.

The present invention is also directed to a method of determining cell charge cycles and parameters.

In a preferred embodiment of the invention, the method of determining cell charge cycles and parameters comprises the method steps for determining the estimated initial state of charge (iSoC) of the cell described above, and the additional step of comparing a corrected iSoC parameter to a predetermined iSoC threshold.

The present invention is also directed to a system for determining an initial state of charge (iSoC) of a cell and, based thereon, cell charge cycles and parameters.

In a preferred embodiment of the invention, the system comprises:

(i) energy acquisition means for receiving external energy, the energy acquisition means being configured to transmit the energy to the cell;

(ii) voltage detection means for detecting open cell voltage (OCV) input and output of the cell;

(iii) current detection means for detecting current (I) input and output of the cell;

(iv) temperature detection means for detecting temperature (T) of the cell;

(v) memory means for receiving and storing a plurality of cell parameters, the memory means being in communication with the voltage detection means, current detection means and temperature detection means, the plurality of cell parameters comprising first open cell voltage (OCV) input and output detected by the voltage detection means, first cell current (I) input and output detected by the current detection means, and first cell temperature (T) detected by the temperature detection means, the plurality of cell parameters further comprising a time to maximum voltage threshold (t_{cv}) of the cell, and a plurality of base line time to maximum voltage threshold (t_{BLCV}) values for at least a second cell; and (vi) processing means for processing the plurality of cell parameters, the processing means being configured to retrieve the plurality of cell parameters from the memory means and determine an estimated initial state of charge (iSoC_{E}) of the cell as a function of the plurality of cell parameters using a predictor-corrector algorithm.

In a preferred embodiment of the invention, the predictor-corrector algorithm is configured to determine a plurality of iSoC parameter values and determine the lowest iSoC parameter value of the plurality of iSoC values.

In a preferred embodiment, the predictor-corrector algorithm is further configured to determine an adjusted time to maximum voltage threshold (t′_{cv}) of the cell and a further adjusted time to maximum voltage threshold (t″_{cv}) of the cell according to the following relationship

t″_{cv}=(1−η)(p)+η(c)

where:
p comprises the lowest iSoC parameter value;
c comprises the adjusted time to maximum voltage (t′_{cv}) of the cell, and
η comprises a correction factor.

In a preferred embodiment, the predictor-corrector algorithm is further configured to compare the further adjusted time to maximum voltage (t″_{cv}) of the cell to the plurality of base line time to maximum voltage (t_{BLCV}) values for a second cell to determine the estimated initial state of charge (iSoC_{E}) of the cell.

### BRIEF DESCRIPTION OF THE DRAWINGS

Further features and advantages will become apparent from the following and more particular description of the preferred embodiments of the invention, as illustrated in the accompanying drawings, and in which like referenced characters generally refer to the same parts or elements throughout the views, and in which:

FIG. 1 is a schematic illustration of a method for determining the initial state of charge (iSoC) of a cell and, thereby, charge parameters for the cell, according to one embodiment of the invention;

FIG. 2 is a schematic illustration of a method for determining a cell iSoC parameter, i.e. cell iSoC parameter one, according to one embodiment of the invention;

FIG. 3 is a schematic illustration of a method for determining another cell iSoC parameter, i.e. cell iSoC parameter two, according to one embodiment of the invention;

FIG. 4 is a schematic illustration of a method for determining yet another cell iSoC parameter, i.e. cell iSoC parameter three, according to one embodiment of the invention;

FIG. 5 is a graphical illustration of cell voltage (V) as a function of charge time (at constant voltage and current) for a nickel metal hydride cell having various initial states of charge (iSoC), according to one embodiment of the invention;

FIG. 6 is a graphical illustration of cell iSoC as a function of time to maximum voltage threshold (t_{cv}) for three nickel metal hydride cells, according to one embodiment of the invention;

FIG. 7 is a graphical illustration showing the relationship between open cell voltage (OCV) and iSoC as a function of cell temperature (T), according to one embodiment of the invention;

FIG. 8 is a graphical illustration of cell charge voltage as a function of time through and to the time to maximum voltage threshold (t_{cv}), according to one embodiment of the invention;

FIG. 9 is a graphical illustration of a further adjusted time to maximum voltage (t″_{cv}), as a function of time (t) during a complete cell charge cycle, according to one embodiment of the invention;

FIG. 10 is a schematic illustration of a system for determining the iSoC of a cell, according to one embodiment of the invention; and

FIG. 11 is a schematic illustration of the detection means subsystems of the system shown in FIG. 10, according to one embodiment of the invention.

### DETAILED DESCRIPTION OF THE PREFERRED EMBODIMENT

Before describing the present invention in detail, it is to be understood that this invention is not limited to particularly exemplified apparatus, systems, structures or methods as such may, of course, vary. Thus, although a number of apparatus, systems and methods similar or equivalent to those described herein can be used in the practice of the present invention, the preferred apparatus, systems, structures and methods are described herein.

It is understood that the terminology used herein is for the purpose of describing particular embodiments of the invention only and is not intended to be limiting.

It is also to be understood that, although the invention is described in connection with nickel metal hydride cells, the methods (and associated apparatus) for determining the initial state of charge (iSoC) for a cell and, based thereon, the charge cycle(s) and parameters for the cell can also be readily employed with other cells, such as, without limitation, alkaline, lead-acid, nickel iron, nickel cadmium, nickel hydrogen, nickel zinc, lithium-air, lithium cobalt oxide, lithium-ion, lithium-ion polymer, lithium iron phosphate, lithium sulfur, lithium titanate, sodium-ion, zinc bromide, zinc cerium, vanadium redox, sodium sulfur and silver oxide cells.

Unless defined otherwise, all technical and scientific terms used herein have the same meaning as commonly understood by one having ordinary skill in the art to which the invention pertains.

Further, all publications, patents and patent applications cited herein, whether supra or infra, are hereby incorporated by reference in their entirety.

Finally, as used in this specification and the appended claims, the singular forms “a, “an” and “the” include plural referents unless the content clearly dictates otherwise.

The following disclosure is provided to further explain in an enabling fashion the best modes of performing one or more embodiments of the present invention. The disclosure is further offered to enhance an understanding and appreciation for the inventive principles and advantages thereof, rather than to limit in any manner the invention. The invention is defined solely by subsequently provided claims, including any amendments made during the pendency of this application, and all equivalents of those claims as issued.

As will readily be appreciated by one having ordinary skill in the art, the present invention substantially reduces or eliminates the disadvantages and drawbacks associated with conventional methods and systems for determining and/or controlling cell charge cycles.

### Definitions

The terms “battery” and “cell” are used interchangeably herein, and mean and include, without limitation, a device comprising one or more electrochemical cells, wherein each cell comprises at least two half-cells connected in series by a conductive electrolyte containing anions and cations that convert stored chemical energy into electrical energy.

The terms “battery” and “cell” also mean and include, without limitation, primary (single charge) and secondary cell (rechargeable) type cells.

The terms “battery” and “cell” thus mean and include, without limitation, the following cell types: wet cells, dry cells, galvanic cells, electrolytic cells, fuel cells, flow cells, Leclanche cells, grove cells, Bunsen cells, chromic acid cell, Clark cell, gel cells, cylindrical cells, button cells, prismatic cells, pouch cells, Daniel cells, Weston cells, nano-cells, and biochemical cells.

The terms “battery” and “cell” also mean and include, without limitation, a cell comprising the following electrochemical compositions: alkaline, aluminum-air, aluminum-ion, lead-acid, lithium, lithium-air, lithium cobalt oxide, lithium-ion, lithium-ion manganese oxide, lithium-ion polymer, lithium iron phosphate, lithium sulfur, lithium titanate, mercury, nickel cadmium, nickel iron, nickel hydrogen, nickel metal hydride, nickel oxyhydroxide, nickel zinc, organic radical, polysulfide bromide, potassium ion, silicon air, silver calcium, silver oxide, silver zinc, sodium-ion, sodium sulfur, vanadium redox, zinc air, zinc bromide, zinc carbon, zinc cerium, and zinc chloride.

The term “initial state of charge” (referred to herein as “iSoC”), means the percentage of a cell's charge remaining relative to the maximum total charge capacity of the cell upon introduction to a charging apparatus and/or any device capable of transmitting current to the cell. As discussed in detail herein, the iSoC is dependent upon a number factors and/or parameters.

The term “current state of charge” (referred to herein as “SoC”), means the percentage of a cell's charge remaining at any given time. As discussed in detail herein, the SoC is similarly dependent upon a number of factors and/or parameters.

The term “initial state of charge threshold” (referred to herein as “iSoC threshold”), means and includes a predetermined SoC value of a cell where charging of the cell is abated, i.e. a charging apparatus and/or any device capable of transmitting current to the cell does not transmit current to the cell and/or initiate a charge cycle.

The term “depth of discharge” (referred to herein as “DOD”) means the expenditure of cell charge relative to the total charge capacity of the cell.

The term “open circuit voltage” (referred to herein as “OCV”) means the difference of electrical potential between two terminals of a device when disconnected from any circuit.

The term “terminal voltage” means the difference of electric potential between two terminals of a device when connected to any circuit.

The term “cell voltage threshold” (referred to herein as “CV”, “CVT” and “CV threshold”) means the maximum voltage potential of a cell.

The term “quiescent recovery”, as used herein, means the rest period required for the completion of the ion transportation and the chemical reactions to stabilize in a cell.

The terms “optional” and “optionally” mean that the subsequently described event, circumstance, or material may or may not occur or be present, and that the description includes instances where the event, circumstance, or material occurs or is present and instances where it does not occur or is not present.

The term “comprise” and variations of the term, such as “comprising” and “comprises,” means “including, but not limited to” and is not intended to exclude, for example, other components or steps.

The following disclosure is provided to further explain in an enabling fashion the best modes of performing one or more embodiments of the present invention. The disclosure is further offered to enhance an understanding and appreciation for the inventive principles and advantages thereof, rather than to limit in any manner the invention.

In overview, the present disclosure is directed to methods and apparatus for determining the initial state of charge (iSoC) and current state of charge (SoC) of a cell and, based thereon, determining the optimum charge cycle(s) and parameters for the cell.

Although the invention is described in terms of a “constant-current/constant-voltage” (CCCV) charging protocol, wherein the cell is charged at a constant current until a prescribed voltage threshold is attained at which point the cell voltage is maintained at that constant voltage threshold, the invention is not limited to CCCV charging protocols. Indeed, the invention is readily extensible to other protocols, such as pulse charging.

It shall also be understood that both the constant charge current (CCC) and the constant voltage threshold, i.e. maximum voltage potential, (CVT) of a cell can, and in most instances, should be adjusted to compensate for cell temperature and other cell parameters or effects, such as aging.

As indicated above, with many cell chemistries, the amount of time required for a cell to attain a constant voltage threshold (CVT) at a constant charge current is strongly related to the iSoC of the cell when the charge cycle is commenced. For example, a fully charged nickel metal hydride (NiMh) cell will require little or no time (i.e. seconds) to attain a constant voltage threshold (CVT). Whereas a fully discharged NiMh cell will require greater than 90 minutes to attain a constant voltage threshold (CVT).

Moreover, with many classes of cells the relationship of time to constant (or maximum) voltage threshold (t_{cv}) and iSoC is generally close to linear, i.e.

iSoC=100%*(1.0−t_{cv}/t_{cc}) Eq. 1

where:
t_{cv} represents the time to constant or maximum voltage threshold of a cell; and
t_{cc} represents a constant current time constant of the cell at a fixed charge current.

According to the invention, the constant current time constant (t_{cc}) corresponds to the amount of time that a totally depleted cell requires to attain a constant or maximum voltage threshold, i.e. t_{cv}. In some embodiments, the fixed charge current is in the range of approximately C/4 to 2C, where C represents the capacity of the cell in mAhours.

According to the invention, fixed charge current values as low as C/20 can be used for trickle charging. Fixed charge current values as high as 10C can be also be used for ultra-rapid charging.

It should, however, be noted that with many cells in certain states of charge, the constant current time constant (t_{cc}) is a small fraction of the total charge cycle time (e.g., <25%). Further, the constant voltage condition is always attained before the charge cycle is complete.

Thus, according to the invention, the time to maximum voltage threshold (t_{cv}) can be used to accurately determine the iSoC and, thereby, by employing coulomb counting, joule counting, timing or other means, accurately determine the current SoC of a charging cell independently of the iSoC when the charge cycle was initiated.

According to the invention, the iSoC and/or the current SoC can also be employed to determine the optimum end point for the charge cycle to maximize the cycle life of the cell.

Additionally, the iSoC and/or the current SoC can be further employed to indicate to an operator (i) the current capacity of the cell and/or (ii) the amount of charge time remaining to attain a fully charged cell state.

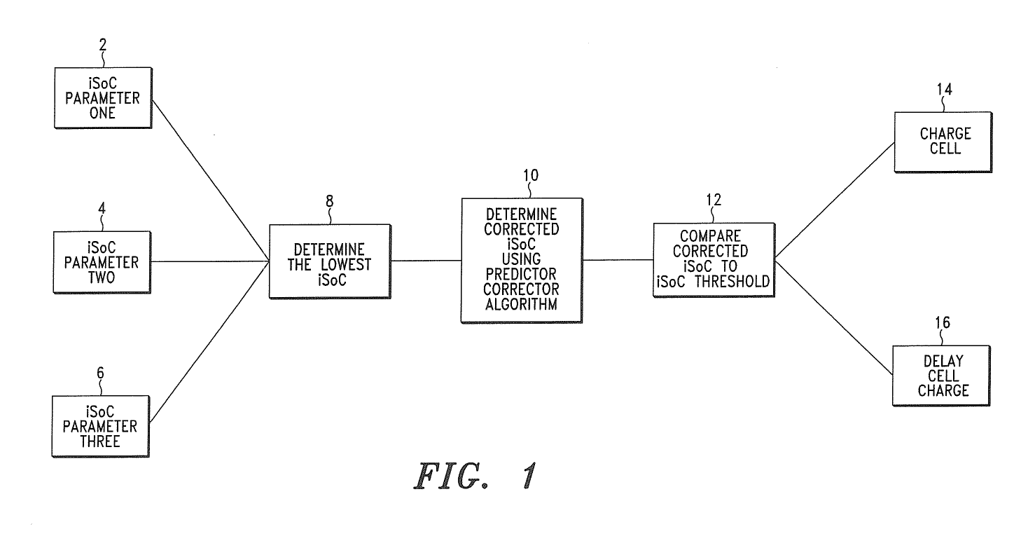

As discussed in detail below, in a preferred embodiment, the method for determining the iSoC for a cell comprises determining three cell iSoC parameters: cell iSoC parameter one 2 (i.e. open circuit voltage), cell iSoC parameter two 4 (i.e. trial discharge) and cell iSoC parameter three 6 (i.e. linear extrapolation) (see FIG. 1). The lowest of the cell iSoC parameters is then determined 8 and employed in a predictor-corrector algorithm to derive a corrected or “adjusted” cell iSoC parameter 10. (see FIG. 1)

As also discussed in detail below, cell iSoC parameter one 2, cell iSoC parameter two 4 and cell iSoC parameter three 6 are determined via relationships by and between a plurality of parameters, such as open cell voltage at a predetermined time, cell temperature, etc.

Referring now to FIGS. 5, 7 and 8, the seminal relationships that are employed to determine cell iSoC parameter one 2, cell iSoC parameter two 4 and cell iSoC parameter three 6 will be discussed in detail.

Referring first to FIG. 5, there is shown a typical relationship of cell voltage (V) and charge time (t) (at a constant voltage and current (I) of 10 mA) for a nickel metal hydride cell having the following cell iSoCs: 0.0% 102, 28.4% 104, 52.3% 106, 64.2% 108, 76.1% 110 and 88.0% 112.

According to the invention, similar cell voltage (V) and charge time (t) relationships or cell iSoC curves, such as curves 102, 104, 106, 108, 110, 112, can be determined for other types of cells, including the cells referenced above. The cell voltage (V) and charge time (t) relationships can then be readily employed to determine cell parameters for other types of cells and related cell chemistries.

As illustrated in FIG. 5, the cell iSoC curves 102, 104, 106, 108, 110, 112 for a nickel metal hydride cell generally exhibit a rapid initial increase in cell voltage (V) until approximately 60 seconds. After approximately 60 seconds, the iSoC curves 102, 104, 106, 108, 110, 112 exhibit linear increases in cell voltage (V).

As the cell iSoC curves 102, 104, 106, 108, 110, 112 approach the constant voltage threshold (CVT) 100, the curves also exhibit a slower increase in voltage (V). Upon reaching the constant voltage threshold (CVT) 100, the voltage (V) represented by the cell iSoC curves 102, 104, 106, 108, 110, 112 remains constant.

According to the invention, the constant voltage threshold (CVT) 100 comprises the maximum voltage (V) capacity of the cell. The time at which the constant voltage threshold (CVT) 100 is reached comprises the time to maximum cell voltage threshold (t_{cv}).

As is well known in the art, the maximum voltage (V) capacity of the cell is dependent on the chemistry of the cell and represents the maximum terminal voltage at which the cell can be charged. With most cell chemistries, the maximum voltage (V) capacity of a cell is also dependent on the temperature of the cell and/or the temperature of the operating environment.

As further illustrated in FIG. 5, lower percentages of cell iSoC, such as represented by iSoC curve 102, exhibit dramatically increased times to maximum voltage threshold (t_{cv}) compared to higher percentages of cell iSoC, such as represented by cell iSoC curve 112. Thus, as evidenced by FIG. 5, the time to maximum voltage threshold (t_{cv}) of the nickel metal hydride cell is generally inversely proportional to the cell iSoC.

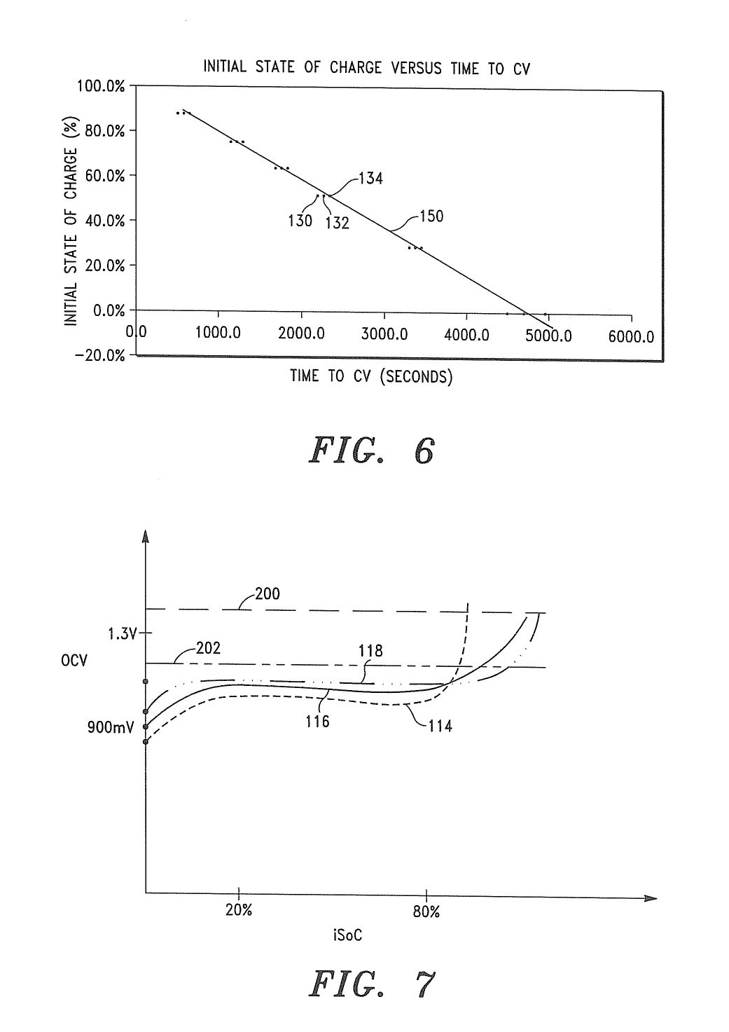

Referring now to FIG. 6, there is shown a typical relationship of iSoC and time to maximum voltage threshold (t_{cv}) for three conventional nickel metal hydride cells 130, 132 and 134. As illustrated in FIG. 6, cells 130, 132, 134 exhibit a similar linear decrease in iSoC as a function of time to maximum voltage threshold (t_{cv}), which is represented by slope 150. Thus, as evidenced by FIG. 6, it is reasonable to conclude that the relationship of iSoC and time to maximum voltage threshold (t_{cv}) will be similar for various cells having similar chemistries.

According to the invention, iSoC, time to maximum voltage threshold (t_{cv}) and cell iSoC curves, such as curves 102, 104, 106, 108, 110, 112, can also be determined for other cells, including the cells referenced above. The cell voltage (V) and charge time (t) relationships can then be readily employed to determine cell parameters for other cells and related cell chemistries.

By way of example, if a cell exhibits an iSoC of approximately 88%, the time to maximum voltage threshold (t_{cv}) will be on the order of a few minutes, e.g. approximately 10 minutes. If the cell exhibits an iSoC of 0%, the time to maximum voltage threshold (t_{cv}) will be on the order of hours, e.g. approximately 1.5 hours.

As is well known in the art, the iSoC that is exhibited by a cell will vary based on the temperature (T) of the cell. Thus, a further relationship that is employed to determine cell iSoC parameter one 2, cell iSoC parameter two 4 and cell iSoC parameter three 6 is the relationship between the cell open cell voltage (OCV) and cell iSoC as a function of temperature (T).

Referring now to FIG. 7, there is shown a typical relationship between OCV of a nickel metal hydride cell and the cell iSoC as a function of temperature (T), where charge voltage curve 114 represents cell OCV as a function of the cell iSoC from 0%-100% at a cell temperature (T) of 15°, charge voltage curve 116 represents the cell OCV as a function of the cell iSoC from 0% -100% at a cell temperature (T) of 25°, and charge voltage curve 118 represents the cell OCV as a function of the cell iSoC from 0%-100% at a cell temperature (T) of 35°.

As illustrated in FIG. 7, the charge voltage curves 114, 116, 118 exhibit a wide range of cell OCV values at cell iSoC percentages in the range of approximately 0%-20% and 80-100%, while exhibiting a substantially narrow range of cell OCV values at cell iSoC percentages in the range of approximately 20%-80%. The cell OCV values at cell iSoC percentages in the range of approximately 20%-80% also remain relatively constant.

Charge voltage curves 114, 116, 118 thus reflect that it is thus very difficult to accurately determine the iSoC of a cell by merely using the relationship between OCV and iSoC alone.

By way of example, as reflected in FIG. 7, a nickel metal hydride cell exhibiting an iSoC percentage in the range of 0%-20% can exhibit an OCV in the range of 900-1200 mV, while a nickel metal hydride cell exhibiting an iSoC percentage in the range of 80%-100% can exhibit an OCV in the range of only 1000-1020 mV.

FIG. 7 also reflects that an increased cell temperature (T) increases the cell OCV at cell iSoC percentages in the range of 0%-20%, while also increasing the time to maximum cell voltage threshold (t_{cv}). By way of example, a nickel metal hydride cell comprising a temperature of 15° C. can exhibit an OCV of 950 mV at an iSoC of approximately 18%, while a nickel metal hydride cell comprising a temperature of 35° C. can exhibit an OCV of 1025 mV at an iSoC of approximately 18%.

Further, a nickel metal hydride cell comprising a temperature of 15° C. exhibits a time to maximum cell voltage threshold (t_{cv}) of approximately 220 minutes, while a nickel metal hydride cell comprising a temperature of 35° C. exhibits a time to maximum cell voltage threshold (t_{cv}) of approximately 300 minutes.

The relationships discussed above and illustrated in FIGS. 5, 6, 7 and 8 are applicable to nickel metal hydride cell chemistry. However, as stated above, according to the invention, similar relationships can be determined for other cells and, hence, cell chemistries, including, without limitation, alkaline, lead-acid, nickel iron, nickel cadmium, nickel hydrogen, nickel zinc, lithium-air, lithium cobalt oxide, lithium-ion, lithium-ion polymer, lithium iron phosphate, lithium sulfur, lithium titanate, sodium-ion, zinc bromide, zinc cerium, vanadium redox, sodium sulfur and silver oxide.

The cell parameters discussed above; particularly, the cell voltage (V), time to maximum voltage threshold (t_{cv}), open cell voltage (OCV) and cell temperature (T) and the relationships therebetween illustrated in FIGS. 5, 6, 7 and 8, demonstrate that cell voltage (V), t_{cv}, OCV and temperature (T) are seminal cell parameters that should be considered and, thus, are considered and employed by the methods of the invention to accurately estimate the iSoC of a cell.

As indicated above and illustrated in FIG. 1, the method of determining the iSoC for a cell comprises determining three iSoC parameters: cell iSoC parameter one 2, cell iSoC parameter two 4 and cell iSoC parameter three 6. The lowest of the cell iSoC parameters is the, determined 8 and employed in a predictor-corrector algorithm to derive a corrected or “adjusted” cell iSoC parameter 10.

The derivation of cell iSoC parameter one 2, cell iSoC parameter two 4 and cell iSoC parameter three 6 will now be discussed in detail.

Cell iSoC Parameter One

According to the invention, cell iSoC parameter one 2 is determined as a function of the cell OCV and temperature (T).

Referring back to FIG. 7, in a preferred embodiment, cell iSoC parameter one 2 comprises a minimum cell iSoC estimate based on charge voltage curves 114, 116, 118. As indicated above, charge voltage curve 114 represents cell OCV as a function of the cell iSoC from 0%-100% at a cell temperature (T) of 15°, charge voltage curve 116 represents the cell OCV as a function of the cell iSoC from 0%-100% at a cell temperature (T) of 25°, and charge voltage curve 118 represents the cell OCV as a function of the cell iSoC from 0%-100% at a cell temperature (T) of 35°.

According to the invention, the initial voltage (V) and temperature (T) of the nickel metal hydride cell are determined to provide the cell OCV at a first (or pre-charge) temperature (T).

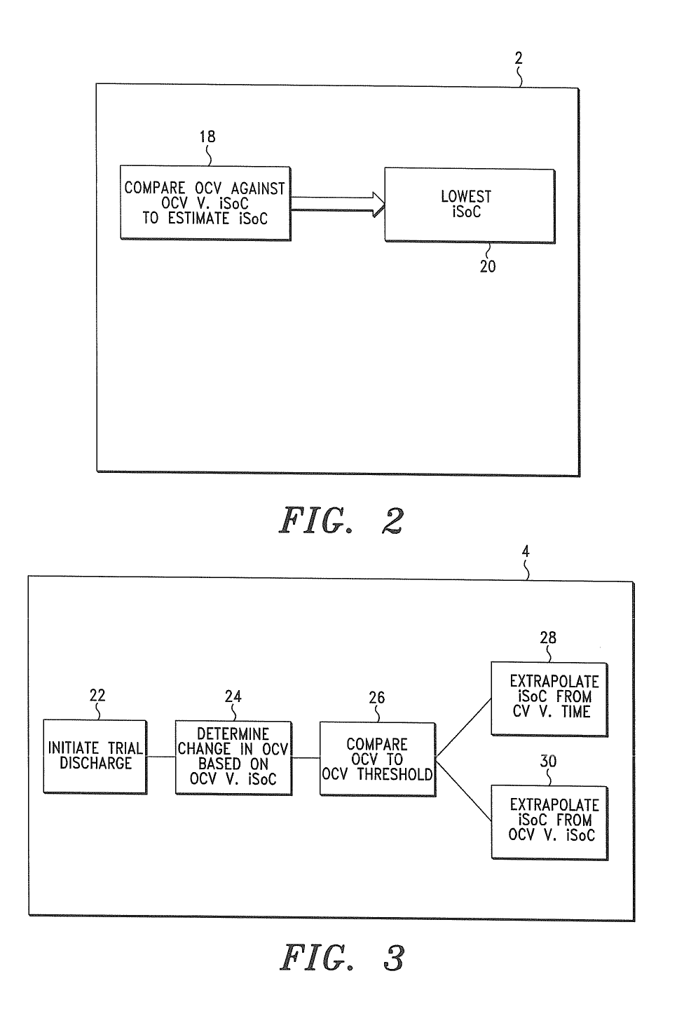

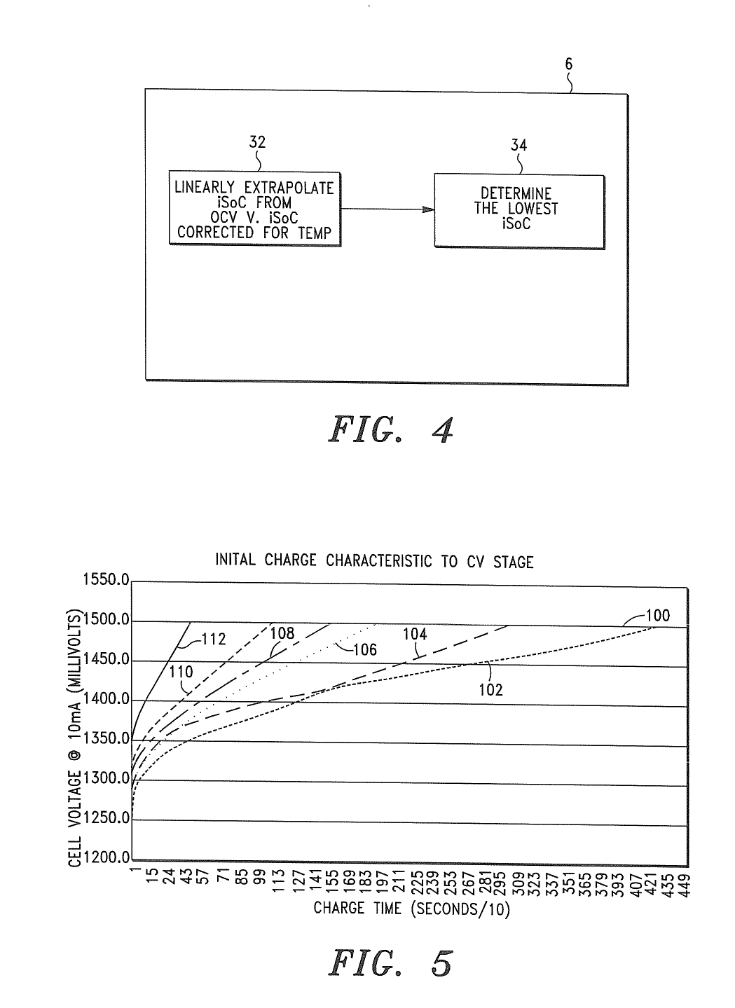

As illustrated in FIG. 2, the detected cell OCV is then compared to a curve representing the cell OCV as a function of cell iSoC based on the detected temperature (T_{detected}) to derive a temperature corrected cell iSoC estimate 18.

According to the invention, the detected cell OCV can be compared against any stored curve(s) representing cell OCV, as a function of cell iSoC, at a wide range of temperatures.

In some embodiments, a plurality of temperature corrected cell iSoC estimates is determined and employed by the methods of the invention.

In a preferred embodiment, cell iSoC parameter one 2 comprises the lowest corrected cell iSoC estimate 20.

As illustrated in FIG. 7, iSoC parameter one 2 is generally accurate at an iSoC in the range of 0-20%, corresponding to a greater time to maximum voltage threshold (t_{cv}), and reduced accuracy of a linear extrapolation of charge voltage curves 114, 116, 118.

Cell iSoC Parameter Two

Referring now to FIG. 3, in a preferred embodiment, cell iSoC parameter two 4 is determined by discharging voltage (V) from the cell at a constant current (Iₜᵣᵢₐₗ) over time (tₜᵣᵢₐₗ) 22 to determine the decrease in cell OCV (mV/min) 24.

In some embodiments of the invention, the cell is discharged at a constant current (Iₜᵣᵢₐₗ) in the range of approximately C/20 to C/5 mA, where C is the milliamp per hour (mAh) rating of the cell.

In a preferred embodiment, the cell is discharged at a constant current (Iₜᵣᵢₐₗ) in the range of approximately C/10 to C/5 mA, more preferably, at a constant current (Iₜᵣᵢₐₗ) of approximately 2 mA, for a 20 mAh cell.

In some embodiments, the cell is discharged with a dynamic current (Iₜᵣᵢₐₗ) in the range of approximately C/100 to 10C mA.

In some embodiments, the cell is discharged with a dynamic current (Iₜᵣᵢₐₗ) in the range of approximately 10C to 1000C mA.

In some embodiments, the trial discharge step comprises a steady-state cell discharge pattern.

In some embodiments, the trial discharge step comprises a pseudorandom pre-discharge pattern.

In some embodiments, the trial discharge step comprises a random discharge pattern.

In some embodiments, the trial discharge step comprises a duration of time (tₜᵣᵢₐₗ) in the range of approximately 1 millisecond-600 seconds.

In some embodiments, tₜᵣᵢₐₗ is in the range of approximately 10 microseconds-1 milliseconds.

In a preferred embodiment, tₜᵣᵢₐₗ is in the range of approximately 30-300 seconds, more preferably, tₜᵣᵢₐₗ is approximately 90 seconds.

In some embodiments, the trial discharge step comprises discharge rest and/or pause periods in the range of approximately 0-600 seconds.

As indicated above, if a cell iSoC is in the range of 0%-20% or 80-100%, there is a wide range of OCV values represented by the slopes of the charge voltage curves 114, 116, 118 shown in FIG. 7.

The trial discharge step typically comprises a substantially greater decrease in cell OCV over time (mV/min) at a cell iSoC in the range of 0%-20% or 80-100%. Referring to FIG. 7, the decreased cell OCV over time (mV/min) corresponds to the regions of the charge voltage curves 114, 116, 118 comprising broad ranges of cell OCV at a cell iSoC in the range of 0%-20% or 80%-100%. According to the invention, the decreased cell OCV thus determines the range of potential cell iSoC estimates.

By way of example, if a trial discharge is employed for a time of 90 seconds (tₜᵣᵢₐₗ) at a constant current of 2 mA, whereby a decrease of cell OCV in the range of 100-150 mV is exhibited, the cell iSoC range is 0%-20% or 80-100%. If a trial discharge is employed for a time of 90 seconds (tₜᵣᵢₐₗ) at a constant current of 2 mA, whereby a decrease of cell OCV in the range of 5-10 mV is exhibited, the cell iSoC range is 20%-80%.

Referring now to FIG. 5, it can be seen that a cell iSoC in the range of 80%-100%, which corresponds to iSoC curve 112, reaches the constant voltage threshold (CVT) 100 in approximately 600 seconds. However, a cell iSoC in the range of 0%-20%, which corresponds to cell iSoC curve 102, will require a greater time (e.g., hours) to reach the constant voltage threshold (CVT) 100. The relationship between cell OCV and iSoC, as a function of temperature, is thus required to accurately determine an estimated iSoC for a cell.

According to the invention, in order to determine whether a substantial decrease in cell OCV over time (mV/min) represents an iSoC in the range of 0%-20% or 80%-100%, an OCV threshold 202 is employed 26 (see FIG. 7).

In some embodiments, the OCV threshold 202 comprises a voltage in the range of approximately 900-1400 mV.

In a preferred embodiment, the OCV threshold 202 comprises a voltage in the range of approximately 1.2-1.25 Volts.

By way of example, if a cell is determined to have an iSoC in the range of either 0%-20% or 80%-100% with a detected OCV of 0.9 V compared to the OCV threshold 202 of 1.2 V, the cell's iSoC is thus deemed to be in the 0%-20% iSoC range. If a cell is determined to have an iSoC in the range of either 0%-20% or 80%-100% with a detected OCV of 1.2 V compared to the OCV threshold 202 of 1.2 V, the cell's iSoC is deemed to be in the 80%-100% iSoC range.

According to the invention, if the cell OCV detected after the trial discharge step meets the OCV threshold 202, the relationship between cell voltage (V) and time (t) at constant current (I), as shown in FIG. 7, is deemed sufficient to estimate the iSoC 28.

Referring now to FIG. 5, it can also be seen that a cell iSoC in the range of 80%-100%, as represented by cell iSoC curve 102, comprises a duration of time of approximately 600 seconds to reach the voltage threshold 100, i.e. t_{cv}, which, according to the invention, is deemed a sufficient time duration to estimate cell iSoC based on cell voltage (V) as a function of time.

According to the invention, if the cell OCV detected after the trial discharge step does not meet the OCV threshold 202, the relationship between cell OCV and the corrected cell iSoC is deemed sufficient and, hence, employed to provide cell iSoC parameter two 30.

In a preferred embodiment, iSoC parameter two 30 is employed to determine the amplitude and phase of the internal impedance (Z) of a cell.

Although iSoC parameter two 30 can be employed to determine the amplitude and phase of the internal impedance (Z) of a cell, the invention is not limited to the use of iSoC parameter two 30 to do so. Indeed, according to the invention, the amplitude and phase of the internal impedance (Z) can be determined using any conventional method of determining internal impedance (Z) of a cell.

In some embodiments, the amplitude and phase of the internal impedance (Z) of a cell is thus determined using conventional methods, including, without limitation Ohm's law, Joule's Law, current-off method, current switch method, energy loss method and the AC internal resistance method.

In some embodiments, the amplitude and phase of the internal impedance (Z) of a cell is determined using a bridge circuit.

Cell iSoC Parameter Three

According to the invention, cell iSoC parameter three 6 is determined as a function of the cell time to maximum voltage threshold (t_{cv}) and the constant voltage threshold (CVT).

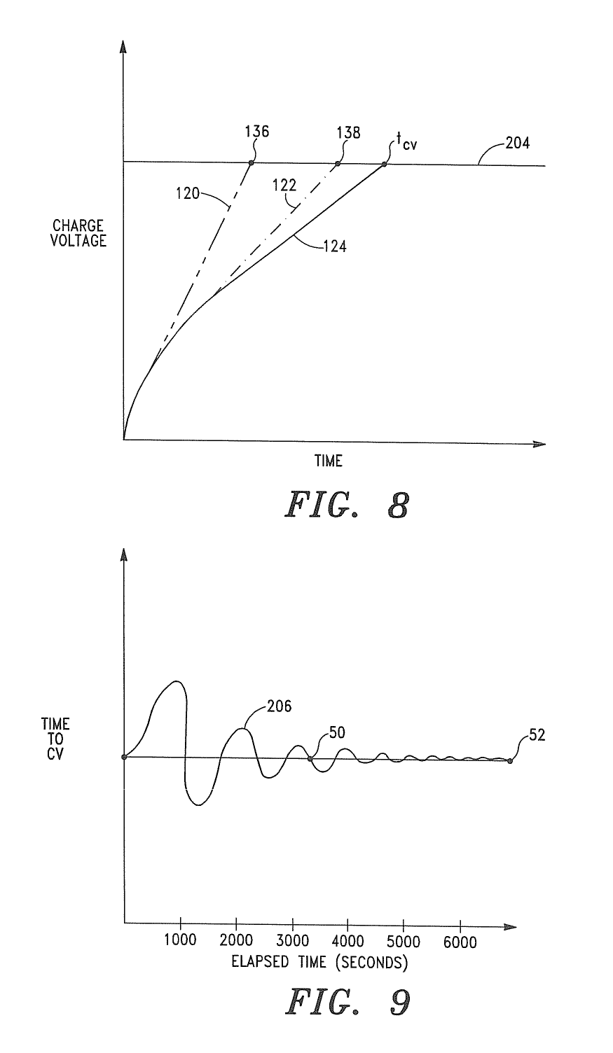

Referring now to FIG. 8, there is shown the typical relationship of cell charge voltage as a function of time, where curve 124 reflects the time to maximum voltage threshold (t_{cv}). As illustrated in FIG. 8, curve 124 becomes progressively linear as the maximum (or constant) voltage threshold (CVT) 204 is approached.

As illustrated in FIG. 8, cell iSoC parameter three 6 is derived by linearly extrapolating curve 124, as represented by line 120, and determining the intersect point 136 of line 120 and the maximum voltage threshold 204.

According to the invention, intersect point 136 represents the “adjusted” estimated time to maximum voltage (t′_{cv}).

According to the invention, the degree accuracy of iSoC parameter three 6 is proportional to the delay of the linear extrapolation of curve 118, which is represented by the intersect point 138 of delayed extrapolated line 122, and the maximum voltage threshold 204.

### Predictor-Corrector Algorithm

As stated above and illustrated in FIG. 1, according to the invention, after cell iSoC parameter one 2, cell iSoC parameter two 4 and cell iSoC parameter three 6 are determined, the lowest cell iSoC parameter value is then determined 8.

As discussed in detail below, the predictor-corrector algorithm of the invention is then employed to determine a corrected (or estimated) cell iSoC 10, as a function of the determined cell iSoC parameters, and cell parameters and relationships therebetween that are reflected in FIGS. 5-9.

Although iSoC parameter three 6 is generally deemed a poor estimate of the time to maximum voltage threshold (t_{cv}) of a cell due to the initial non-linearity of curve 124, iSoC parameters one through three 2, 4, 6 are initially employed to simply provide a user of the current SoC and remaining charge time of the cell.

It is, however, advantageous to initially underestimate the iSoC; particularly, if a conventional “Bar Graph” form of user interface will be used to indicate the charge status, because an initial “underestimated” iSoC will provide an iSoC value that always increases with charge time and will never stall. In contrast, an over-estimated iSoC will require an indicator value that either stalls for a period of time or decreases in value to compensate for the iSoC over-estimate.

Thus, in a preferred embodiment of the invention, the lowest cell iSoC 8 is used as the initial estimate of the cell iSoC as it often underestimates the true iSoC. According to the invention, the initial iSoC estimate corresponds to a predicted cell OCV based on the relationship of cell OCV and iSoC as a function of temperature (T).

As stated above, iSoC parameter three 6 is generally deemed a poor estimate of the time to maximum voltage (t_{cv}) of a cell due to the initial non-linearity of curve 124. However, as illustrated in FIG. 8, curve 124 becomes more linear as the maximum voltage threshold 204 is approached, and also because the amount of time extrapolated, i.e. extrapolation leverage, becomes smaller and smaller as the maximum voltage threshold 204 is approached. The accuracy of the iSoC parameter three 6 thus progressively increases as a function of time.

As indicated above, after cell iSoC parameter one 2, cell iSoC parameter two 4 and cell iSoC parameter three 6 are determined, the predictor-corrector algorithm is then employed to determine a corrected (or estimated) cell iSoC 10 (see FIG. 1), as a function of the determined cell iSoC parameters, and cell parameters and relationships therebetween that are reflected in FIGS. 5-9.

In a preferred embodiment, the predictor-corrector algorithm initially determines a further adjusted time to maximum voltage threshold (t″_{cv}) at any given time before the maximum cell voltage (V) attained according to the following equation:

t″_{cv}=(1−η)(p)+η(c) Eq. 2

where:
p comprises the predictor component of the predictor-corrector algorithm, which, in a preferred embodiment, comprises the lowest iSoC parameter of said cell;
c comprises the corrector component of the predictor-corrector algorithm, which, in a preferred embodiment, comprises the adjusted time to maximum voltage (t′_{cv}) of said cell, and
η comprises a correction factor, which, in a preferred embodiment, is in the range of 0 to 1, i.e. 0<η<1.

According to the invention, t can either be solved iteratively or can be obtained as the larger root of the quadratic equation, as shown in Eq. 2 below:

(t″_{cv})²−p×t″_{cv}=2×t_{cv}×(p−c) Eq. 3

In a preferred embodiment, the predictor-corrector algorithm executes simultaneously with the charge cycle of the cell.

In a preferred embodiment, the predictor-corrector algorithm comprises both a predictor comprising an explicit determination method and a corrector comprising an implicit determination method.

According to the invention, various additional predictor methods can be employed within the scope of the invention, including, without limitation, cell pulse current response, pulse voltage response, AC impedance, DC impedance and combinations thereof over a broad range of settings.

According to the invention, various additional corrector methods can also be employed within the scope of the invention, including, without limitation, pulse current response, pulse voltage response, AC impedance, DC impedance, and combinations thereof, over a broad range of settings.

Referring now to FIG. 9, there is shown a graphical representation of the further adjusted time to maximum voltage threshold (t″_{cv}), as determined by the predictor-corrector algorithm of the invention, as a function of time (t) during a complete cell charge cycle. As illustrated in FIG. 9, at a period of time (t) from 0-6000 seconds during the charge cycle, the predictor-corrector algorithm determines a broad range of further adjusted time to maximum voltage threshold (t″_{cv}) values that decrease over time. The noted decrease in further adjusted time to maximum voltage threshold (t″_{cv}) values reflects incrementally increasing accuracy of t″_{cv}, as determined by the predictor-corrector algorithm during a cell charge cycle.

According to the invention, the predictor-corrector algorithm continually determines the further adjusted time to maximum voltage threshold (t″_{cv}) values during (i.e. simultaneously with) the charge cycle of the cell through and to an end time denoted by point 52. As discussed in detail below, in a preferred embodiment of the invention, end point 52 is determined by the voltage (V) of a cell at a given time point of the charge cycle being within a predetermined tolerance value (V′) of the maximum voltage threshold (CVT).

According to the invention, the tolerance value (V′) can be adjusted for any environmental factor, including, without limitation, temperature, number of charge cycles, cell chemistry, cell load, number of cells, and iSoC of the cell.

As also discussed in detail below, the further adjusted time to maximum voltage threshold (t″_{cv}) values determined by the predictor-corrector algorithm during a cell charge cycle are then employed to derive predicted (or estimated) iSoC values with similarly incrementally increasing accuracy and, hence, estimated current SoC values that also increase in accuracy over time.

A seminal variable in the predictor-corrector algorithm reflected in Eq. 1 above is the correction factor η. In a preferred embodiment of the invention, correction factory η is determined according to the equation 3 below, i.e.

η=% c=K×(t_{cv}/t″_{cv}) Eq. 4

where:

### K=2; and

η=1 when K×t_{cv}>t″_{cv}

Referring now to FIG. 9, in a preferred embodiment of the invention, correction factor η provides a condition such that, when the actual time “t_{cv}” reaches 50% (or ½) the estimated time “t_{cv},” (denoted by point 50), the predictor component of the predictor-corrector algorithm is terminated, while the corrector component continues to execute until an end time 52.

However, in some embodiments of the invention, a value of K less than 2 is employed to determine correction factor η. Such embodiments are deemed “predictor heavy” and continue to use the predictor component of the predictor-corrector algorithm until after half the time to maximum voltage (t_{cv}) cycle is completed.

In some embodiments of the invention, a value of K greater than 2 is employed to determine correction factor η. Such embodiments are deemed “predictor light” and terminate the use of the predictor component of the predictor-corrector algorithm before half the time to maximum voltage (t_{cv}) cycle is completed.

In some embodiments, the value of K is varied during the time to maximum voltage (t_{cv}) cycle using other parameters. By way of example, a measurement of the linearity of a cell's voltage history to dynamically optimize the accuracy of the best estimator of time to maximum voltage (t_{cv}).

Referring again to FIG. 6, iSoC curves 112, 110, 108, 106 exhibit substantially linear asymptotic behavior, whereas iSoC curves 104, 102 exhibit substantially non-linear artifacts in their behavior. According to the invention, the linear asymptotic behavior of iSoC curves 112, 110, 108, 106 can be used to dynamically adjust the value of K in a manner that favors the corrector component of the predictor-corrector algorithm. Conversely, the non-linear artifacts in the behavior of iSoC curves 104, 102 can be used to dynamically adjust the value of K in a manner that favors the predictor component of the predictor-corrector algorithm.

According to the invention, at end time 52 shown in FIG. 9, the predictor-corrector algorithm determines a corrected cell SoC value, which corresponds to a corrected cell iSoC, based on the relationship of the cell iSoC and time to maximum voltage (t_{cv}) as a function of temperature (T), as illustrated in FIG. 6.

The methods for determining the charge cycles and parameters of the cell will now be described in detail.

In a preferred embodiment of the invention, the first step in determining the charge cycles and parameters of the cell comprises comparing the corrected cell iSoC (determined by the relationships and algorithms described above) to the cell iSoC threshold 12, e.g. 80% iSoC.

Referring back to FIG. 1, according to the invention, if the corrected cell iSoC does not meet the cell iSoC threshold 12, the cell's charge cycle continues 14. If the corrected cell iSoC meets the cell iSoC threshold 12, the cell's charge cycle is delayed 16.

According to the invention, the cell iSoC threshold 12 can comprise any pre-determined arbitrary value to limit the number of cell charge cycles and, hence, extend the life cycle of the cell. By way of example, if a cell iSoC threshold 12 comprises a value of 90% iSoC and the predictor-corrector algorithm determines that the cell comprises an iSoC of 88%, the cell charge cycle will not initiate. Thus, by employing the method of the invention, the number of charge cycles is limited based on the iSoC threshold 12, whereby the cell chemistry is preserved and operational life of a cell is extended.

According to the invention, the cell iSoC threshold 12 can comprise any iSoC value in the range of 0 to 100%.

Systems and apparatus for determining the above referenced cell parameters; particularly, the cell iSoC, and charge cycle(s) and parameters based thereon, will now be described in detail.

According to the invention, various systems and apparatuses can be employed within the scope of the invention to determine the above referenced cell parameters, i.e. t_{cv}, t′_{cv}, t^{″}_{cv}, OCV values, iSoC, etc., and the optimum charge cycle(s) and parameters based thereon. One exemplary system is described in detail below.

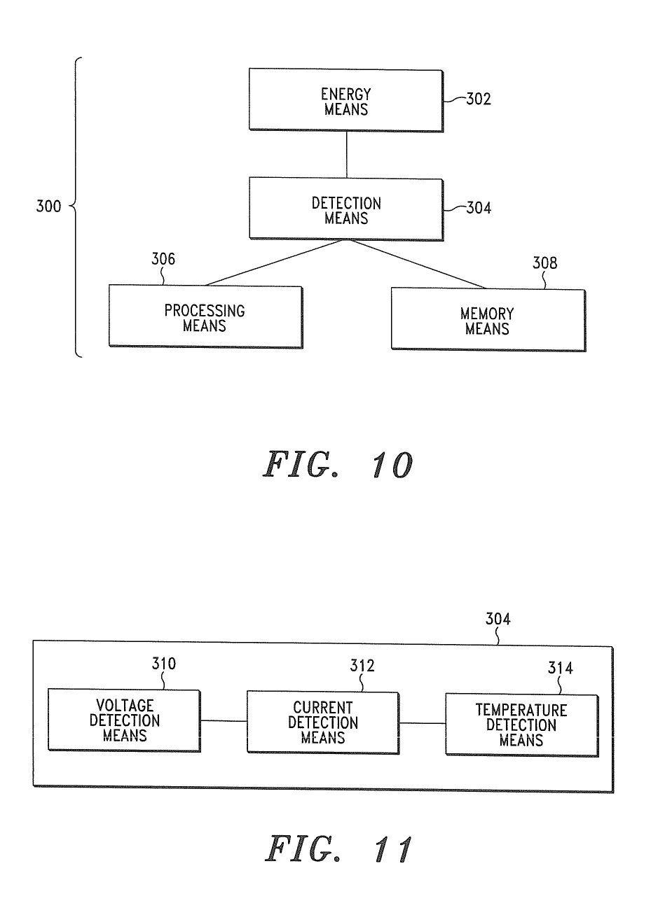

Referring now to FIG. 10, the exemplary system 300 comprises energy means 302, detection means 304, processing means 306 and memory means 308. As illustrated in FIG. 10, the system processing means 306 is preferably in direct communication with the detection means 304, memory means 308 and system input-output interfaces.

According to the invention, the energy means 302 can comprise a cell or energy acquisition means. In a preferred embodiment of the invention, the energy means 302 is configured to receive external energy and transmit the energy via current (I) to a cell that is in communication with the system 300.

In some embodiments, the energy means 302 comprises an electromagnetic field source that is configured to transmit current (I) to the system 300 and, hence, a cell that is in communication therewith, i.e. inductive charging.

Referring now to FIG. 11, the detection means 304 preferably comprises voltage detection means 310 that is configured to detect voltage (V) input and output of the system 300 and a cell that is in communication therewith. According to the invention, suitable voltage detection means 310 include, without limitation, a voltage meter and electric field strength meter.

As illustrated in FIG. 11, the detection means 304 further comprises current detection means 312 that is configured to detect current (I) input and output of the system 300 and a cell that is in communication therewith. According to the invention, suitable current detection means 312 include, without limitation, a current meter and magnetic field strength meter.

The detection means 304 further preferably comprises temperature detection means 314 that is configured to detect temperature (T) of system 300 and a cell that is in communication therewith. According to the invention, suitable temperature detection means 314 include, without limitation, a thermistor, thermocouple and a semiconductor temperature measurement device.

As illustrated in FIG. 10, the system 300 further comprises memory and processing means 308, 306. As further illustrated in FIG. 10, the memory means 308 is in communication with the processing means 306.

According to the invention, the memory means 308 can comprise various conventional memory means.

In some embodiments, the memory means 308 thus comprises volatile memory. According to the invention, suitable types of volatile memory include, without limitation, dynamic random access memory (DRAM), double data rate synchronous dynamic random access memory (DDR SRAM) and static random access memory (SRAM).

In some embodiments, the memory means 308 comprises non-volatile memory. According to the invention, suitable types of non-volatile memory include, without limitation, mask read-only memory (Mask ROM), programmable read-only memory (PROM), erasable programmable read-only memory (EPROM), electronically erasable programmable read-only memory (EEPROM), magnetic non-volatile memory and non-volatile random access memory (NVRAM).

In some embodiments of the invention, the memory means 308 comprises an integral subsystem or component of the processing means 306.

In a preferred embodiment of the invention, the memory means 308 is programmed and configured to receive and store at least the predictor-corrector algorithm of the invention, as well as the cell parameter relationships described herein and cell parameters determined therefrom.

In a preferred embodiment, the memory means 308 thus includes at least the cell parameter relationships illustrated in FIGS. 5 and 6 for at least one cell chemistry, e.g. nickel metal hydride, more preferably, a plurality of cell parameter relationships for a plurality of cell chemistries.

The memory means 308 is also configured to receive and store data detected/received by the detection means 304 of the system 300, i.e. voltage (V), current (I), and temperature (T) of a cell.

According to the invention, the processing means 306 can similarly comprise various conventional processing means, including, without limitation, a microprocessor, microcontroller, dedicated digital logic, dedicated analog logic and analog computer.

In preferred embodiment, the processing means 306 comprises a microprocessor.

In a preferred embodiment, the processing means 306 is programmed and configured to retrieve the cell parameters, algorithms, etc. that are stored in the memory means 308, and process the retrieved information in accordance with the above discussed methods of the invention.

In a preferred embodiment, the processing means 306 is thus configured to retrieve the cell parameters and relationships discussed above and illustrated in FIGS. 5, 7 and 8, and determine cell iSoC parameter one 2, cell iSoC parameter two 4 and cell iSoC parameter three 6, and, based thereon, a corrected cell iSoC.

In a preferred embodiment, the processing means 306 is further configured to employ the corrected cell iSoC to modulate the system 300 energy and current (I) and, hence, the energy and current transmitted to a cell that is in communication with the system 300.

One having ordinary skill in the art will thus readily appreciate that the apparatus and methods of the invention provide numerous advantages over conventional apparatus and methods for modulating the charge parameters for a cell. Among the advantages are the following:

The provision of methods and apparatus that are configured to readily and accurately determine the iSoC and SoC of a cell and, based thereon. the optimum charge cycle(s) and parameters for the cell;
The provision of methods and apparatus for modulating cell charge cycles and parameters that are configured to provide a cell iSoC voltage threshold to limit additional charge cycles, whereby the operational life of the cell is extended;
The provision of methods and apparatus for modulating cell charge cycles and parameters that are configured to prevent the transmission of current to a cell exhibiting maximum cell voltage, which prevents aberrant and often irreversible changes in the cell's chemistry; and
The provision of methods and apparatus for determining cell parameters that provide useful feedback to the user such as accurately determined current SoC and accurately determined remaining charge time communicated through some interface device.

Without departing from the spirit and scope of this invention, one of ordinary skill can make various changes and modifications to the invention to adapt it to various usages and conditions. As such, these changes and modifications are properly, equitably, and intended to be, within the full range of equivalence of the invention.

What is claimed is:

1. A system for estimating an initial state of charge (iSoC) of a cell, said cell being in communication with said system, comprising:
energy acquisition means for receiving external energy, said energy acquisition means being configured to transmit said energy to said cell:
voltage detection means for detecting open cell voltage (OCV) input and output of said cell:
current detection means for detecting current (I) input and output of said cell;
temperature detection means for detecting temperature (T) of said cell;
memory means for receiving and storing a plurality of cell parameters, said memory means being in communication with said voltage detection means, current detection means and temperature detection means,
said plurality of cell parameters comprising first open cell voltage (OCV) input and output detected by said voltage detection means, first cell current (I) input and output detected by said current detection means, and first cell temperature (T) detected by said temperature detection means, said plurality of cell parameters further comprising a time to maximum voltage threshold (t_{cv}) of said cell, and a plurality of base line time to maximum voltage threshold (t_{BLCV}) values for at least a second cell; and
processing means for processing said plurality of cell parameters, said processing means being configured to retrieve said plurality of cell parameters from said memory means and determine an estimated initial state of charge (iSoC_{E}) of said cell as a function of said plurality of cell parameters using a predictor-corrector algorithm.

2. The system of claim 1, wherein said predictor-corrector algorithm is configured to determine a plurality of iSoC parameter values and determine the lowest iSoC parameter value of said plurality of iSoC values.

3. The system of claim 1, wherein said predictor-corrector algorithm is further configured to determine an adjusted time to maximum voltage threshold (t′_{cv}) of said cell and a further adjusted time to maximum voltage threshold (t″_{cv}) of said cell according to the following relationship
t″_{cv}=(1−η)(p)+η(c)
where:
p comprises said lowest iSoC parameter value;
c comprises said adjusted time to maximum voltage (t′_{cv}) of said cell, and
η comprises a correction factor.

4. The system of claim 3, wherein said predictor-corrector algorithm is further configured to compare said further adjusted time to maximum voltage (t″_{cv}) of said cell to said plurality of base line time to maximum voltage (t_{BLCV}) values to determine said estimated initial state of charge (iSoC_{E}) of said cell.
